(19) United States
(12) Patent Application Publication
(10) Pub. No.: US 2007/0109171 A1
(43) Pub. Date: May 17, 2007

(54) Audio ouput soft start by use of output driver enable signal

(75) Inventors: Andrew Martin Mallinson, Kelowna (CA); Elim Huang, Cupertino, CA (US)

Correspondence Address: STEVENS LAW GROUP, P.O. BOX 1667, SAN JOSE, CA, 95109, US

(73) Assignee: ESS Technology, Inc., Fremont, CA (US)

(21) Appl. No.: 11/432,985

(22) Filed: May 12, 2006

Related U.S. Application Data
(60) Provisional application No. 60/680,210, filed on May 12, 2005.

(51) Int. Cl. H03M 1/12

(52) U.S. Cl. 341/155

(57) ABSTRACT

A system and method are provided for signal processing between any two or more connected analog signal processing elements, including a plurality of analog processing elements connected via DC blocking capacitors and a signal processing element that operates as the source of the signal employing a controlling means to adjust its output impedance.

### PRIORITY

This application claims priority based on provisional application No. 60/680,210 which was filed on May 12, 2005.

### BACKGROUND

The use of direct circuit (“DC”) blocking capacitors to remove a DC offset while generating analog outputs is well known in conventional systems. In one example, DC blocking capacitors are used in circuits that provide an analog output signal that is then fed to a power amplifier.

The invention is generally directed to two scenarios: the first case is the common one where an analog output signal is connect to an analog input signal having differing notions of the zero signal voltage and hence requiring a DC block capacitor. The second case is perhaps less common where a Pulse Width Modulation process is generating the analog signal as an average output value that must be filtered to create the appropriate analog signal in the band of interest prior to connection to a subsequent analog signal processing block. This second case also having a differing notion of the zero signal and also therefore requiring a DC blocking capacitor. Our motivation in describing two scenarios is that the invention is easily seen in the PWM case (and indeed the inventor first realized the possibility of this invention in the PWM case) however, once determined and developed for the PWM case it becomes clear that the invention also applies in the common analog signal output to analog signal input case as well.

Perhaps less well known than in the case of an analog signal connecting two analog processing blocks together, the need for a DC blocking capacitor also can arise when an output is a Pulse Width Modulated (PWM) signal whose average value is the desired analog signal. An example of such a circuit configuration includes a pair of FET (field-effect transistor) devices connected together in parallel, and then further connected at one end in series to a filter. In operation, an analog output is created by averaging the discreet output pulses from the FET devices.

In a more particular example for use in an integrated circuit formed on a micro chip, a first FET device is connected to ground and a second FET device is connected to a positive voltage rail. This is due to the fact that they are on-chip components, and the ground and positive terminals are the Vss and Vdd of the chip respectively. In a more specific example, the value for Vss is zero volts and the value for Vdd is 3.3 volts. In operation, the FETs are driven by a digital signal. To represent the most negative signal, the FET connected to zero volts is turned on, while the FET connected to 3.3v is turned off. The situation is reversed to represent the most positive output, where the FET connected to zero volts is turned off, and the FET connected to 3.3v is turned on. To represent a quiet or nominally zero signal, a relatively high frequency switching between these two states is typically employed, with each FET turning on and off in turn. This is done in a manner in which one FET operates anti-phase to the other FET. Thus, the offset voltage output for a quiet signal from such a circuit configuration would not be zero on average; rather it would be offset from ground. In this example, the nominal output voltage representing a quiet signal could be 1.65v, or half way between zero volts and 3.3v

In practice, audio equipment components that make use of PWM circuits are typically connected to the blocking capacitor circuit after a filter, the filter being designed to remove the relatively high switching frequency that drives the FETS, leaving only the desired average output signal represented by the duty cycle of that switching signal. The connected audio equipment would require an input from the circuit to have an average value of zero, one that is not offset from ground. To remove such a DC offset, a DC blocking capacitor is commonly provided between the source (in this case the switching FETS and filter arrangement) and the audio equipment. Therefore, as can be seen in this example of a PWM operating from 0 to 3.3v a DC blocking capacitor is required.

Although the introduction of the DC blocking capacitor removes the offset, its incorporation into the circuit creates a new problem. During the first application of power to the chip, the DC voltage across the DC blocking capacitor must adjust so that there is no DC offset. For example, if the positive power were 3.3v, the mean voltage output from the FET devices and the filter would typically be 1.65v. Therefore, the DC blocking capacitor must accumulate sufficient charge to have an average of 1.65v across it. Thus, the initial flow of charge to the DC blocking capacitor causes a click or thud sound in an audio sound system as power is first applied to the chip. This click or thud is manifested in a sound from the audio speakers, and can be distracting to the operator or listener of audio equipment. Note that this problem is present in the common analog signal and the in PWM signal as well.

Therefore, there exists a need for a method and system of improved power delivery to a blocking capacitor that is positioned before audio equipment. As will be seen, the invention accomplishes this in a unique and elegant manner.

### BRIEF DESCRIPTION OF THE DRAWINGS

FIG. 1 is a circuit configured according to the invention;

FIG. 2 is a circuit configured according to the prior art;

FIG. 3 is a circuit configured according to the invention;

FIG. 4 is a circuit configured according to the invention;

FIG. 5 is a flow chart configured according to the invention;

### DETAILED DESCRIPTION

According to the invention, a system and method are provided that may be employed between any two or more connected analog signal processing elements, where those connections are made by use of DC blocking capacitors. In one embodiment, two Field Effect Transistors (FETs) are configured to create a PWM output. The invention further extends to any configuration where the output of the driving element may have its impedance changed from a relatively low (operating) to a relatively high (“off” state) and our invention allows the use of the off state to control the initial current into the DC blocking capacitor and so applies to the PWM and to the analog I/O case equally. The invention is directed to a system and method that applies to the PWM and the analog I/O case. This is described further below.

According to the invention, a signal processing element operates as the source of the signal employing an additional connection or controlling means whereby its output impedance may be adjusted. The invention is directed to the use of this additional impedance controlling connection as a means to moderate or otherwise beneficially control the establishment of the DC voltage across a DC blocking capacitor. In operation, the ability to control the impedance would be beneficial when the state of voltage representing a nominally zero signal is changed. Such an application may include the change of DC voltage level that may be present upon first application or final removal of power on analog processing elements, particularly between any analog input and any analog output of an Audio signal processing path.

In its broadest sense, the invention provides a signal processing circuit having a first analog signal processing element, a second analog signal processing element and a direct current blocking capacitor connecting the first and second analog signal processing elements. It further provides a controller configured to adjust the impedance of the first analog signal processing element in response to an adjustment signal, wherein the controller is configured to enable the controlling of the establishment of a voltage across the direct current blocking capacitor. The analog signal-processing element may be one of a pre-amplifier output, a DAC output, a microphone amplifier output, and any source of an analog audio signal also including a PWM output configured to generate an average output signal. The second device may be one of the inputs to a power amplifier, a subsequent analog amplification, a processing stage, an ADC converter, a passive element, a loudspeaker, a headphone device and a power bridge device configured to output a high power within an audio system. The controller may be configured to control the establishment of a voltage as may be required when the state of voltage representing a nominally zero signal is changed. The controller may alternatively be configured to control the establishment of the DC voltage as may be required when the state of voltage representing a nominally zero signal is changed, such as in the event of a change of DC voltage level that may be present upon one of 1) the first application and 2) the final removal of power on either of the analog processing elements. The circuit may further comprise an outside signal source transmitting a signal to the controller to control the establishment of the DC voltage. The DC voltage may originate in a multiplexing device that is configured to switch an audio signal from one audio program to another as may be used to select TV or DVD or CD or similar. The circuit may further include an outside signal source transmitting a signal to the controller to control the establishment of the DC voltage, such as that which may be required when the state of voltage representing a nominally zero signal is changed. The controller may be configured to control the establishment of the DC voltage across the DC blocking capacitor as may be required when the state of voltage representing a nominally zero signal is changed. The controller may be configured to control the establishment of the DC voltage across the DC blocking capacitor in the event of a change of DC voltage level. The controller is configured to control the establishment of the DC voltage across the DC blocking capacitor in the event of a change of DC voltage level upon the first application of power upon either of the analog processing elements.

The system may be configured for signal processing between any two or more connected analog signal processing elements, and it may include a plurality of analog processing elements connected via DC blocking capacitors and a signal processing element that operates as the source of the signal employing a controlling means to adjust its output impedance. The controlling means may control the establishment of the DC voltage across the DC blocking capacitor such as may be required when the state of voltage representing zero signal is changed. The voltage representing a nominally zero signal includes a change of DC level that may be present upon first application and final removal of power on an analog processing elements. The additional impedance controlling means may be configured to select one of a finite set of predetermined output impedances. The control of the establishment of the DC voltage across the DC blocking capacitors may be achieved by a sequence of selection of predetermined output impedances. The impedance controlling means may be configured to select one of two possible output impedances, one a nominally low impedance as may be used in normal operation, and another a nominally high impedance for blocking any substantial current flow. The control of the establishment of the DC voltage across the DC blocking capacitors may be achieved by the application of a binary sequence of bits to the controlling means. The sequence of binary bits is configured such that the average output impedance over a defined interval is of a value between that of a nominally low and that of a nominally high output impedance. The sequence of binary bits is constructed such that the output impedance over a defined interval of time progresses gradually from the nominally high output impedance down to the nominally low output impedance to establish the DC value upon either of the first application of power and the first establishment of the nominal operation of any of the analog processing elements. The sequence of binary bits may be configured such that the output impedance over a defined interval of time progresses gradually from the nominally low output impedance up to the nominally high output impedance as may be desirable to establish the DC value upon either of the removal of power and the termination of the nominal operation of any of the analog processing elements. The sequence of selection of predetermined output impedances applied to the additional impedance controlling means may be at a frequency that is outside a defined range of frequencies transmitted across the connection between the analog signal processing elements. The frequency of selection of predetermined output impedances may be at a frequency higher than a frequency transmitted across the connection between the analog signal processing elements.

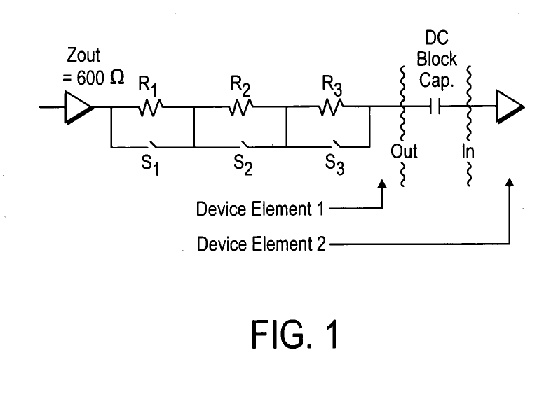

In one embodiment, an additional impedance controlling connection or means selects one of a finite set of predetermined output impedances. Referring to FIG. 1, a device is illustrated having a having a 600Ohm output impedance, which is the low output impedance present during the normal operation of the device. Devices R1-R3 and S1-S3 operate to control a set of other possible higher output impedances such that the output impedance is higher (the “off” impedances). For example, if S 1 s2 and s3 are all closed the nominal 600 ohms output is used and the device is operating in the normal manner. If S3 is open (S1 and S2 remaining closed), then the output impedance is 600+R3. Similarly if S2 is open the output impedance is 600+R3+R2 etc. This is one example of a case where the output impedance differs by more then two discrete values.

The moderation or otherwise beneficial control of the establishment of the DC voltage across the DC blocking capacitors may be achieved by a sequence of selection of these predetermined output impedances. For example, R3 may have a very high impedance, indeed it may be nominally infinite. Upon first establishing power, or removing power, the switch S3 may be open, therefore the output will have the high R3 impedance value plus the nominal 600 output impedance. Very little current, only that through the very high R3 value, is available to charge the capacitor. Therefore, no initial or final click is heard. In order to establish the DC blocking voltage, S2 is now opened and S3 is closed. Now the output impedance is 600+R2. R2 may be a high value resistor, but not as high as R3, for example, it may be 1 MegOhm. Now, a few micro amps are typically available to charge the capacitor, but the rate of charge is low. No click is heard because the voltage is changing slowly. Now S1 is opened and S2 closed. Now the output impedance is 600+R1. R1 may be lower than R2, for example, 10 k. Now the voltage moves more quickly to the DC voltage and the click is not heard because the total voltage disturbance is small. The voltage was almost reached by R2. Finally S1 is closed, the output impedance drops to the nominal 600 ohms and the circuit is ready to operate. The sequence may be reversed just before power off.

Another method further includes additional steps, where the additional impedance controlling connection or means selects one of two possible output impedances, one a nominally low impedance as may be used in normal operation, one a nominally high impedance as may be used to block any substantial current flow.

The moderation or otherwise beneficial control of the establishment of the DC voltage across the DC blocking capacitors then being achieved by the application of a binary (two-valued) sequence of bits to the controlling connection or means.

The sequence of binary bits so provided being constructed such that the average output impedance over a defined interval is of a value between that of the nominally low and that of the nominally high output impedance.

Yet another method includes further steps wherein the sequence of binary bits is constructed such that the output impedance over a defined interval of time progresses gradually from the nominally high output impedance down to the nominally low output impedance as may be desirable to establish the DC value upon the first application of power or the first establishment of the nominal operation of any of the analog processing elements. Yet another method is included wherein the sequence of binary bits is constructed such that the output impedance over a defined interval of time progresses gradually from the nominally low output impedance up to the nominally high output impedance as may be desirable to establish the DC value upon the removal of power or the termination of the nominal operation of any of the analog processing elements.

Yet another method is included wherein the sequence of selection of predetermined output impedances applied to the additional impedance controlling connection or means is at a frequency that is outside the band of frequencies normally transmitted across the connection between the analog signal processing elements.

In another method, the frequency of selection of predetermined output impedances is at a frequency higher than the frequency normally transmitted across the connection between the analog signal processing elements. Here, this is the case where essentially continuous impedance is created by switching with a variable mark-space ratio (variable duty cycle) between two impedances. To do this such that it is “essentially continuous” requires that the switching speed be greater than the maximum signal frequency that the channel can carry. Thus, it is “out of band” and not perceived as a spurious signal in the channel.

A tri-state circuit has an additional input that enables the circuit. When the value of the enable input is equal to 1, the tri-state circuit operates like a traditional circuit. When the value of the enable input is equal to zero, the output of the tri-state circuit is disconnected from the rest of the circuit and effectively turned off. On operation, the enable input acts like a switch on the output of the tri-state circuit. The switch is open when the enable value is equal to 0 and is closed when the enable value is equal to 1.

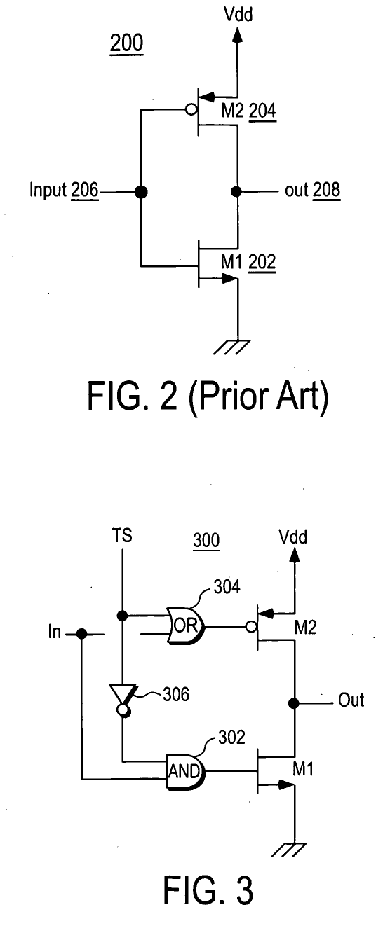

Referring to FIG. 2, a conventional configuration of a “PWM” output used as an analog audio signal source 200 is shown having a NMOS 202 and a PMOS 204 device connected to a common input terminal 206. M1, the NMOS device 202, is connected with its source at ground and its drain at the output node 208. M2, the PMOS device 204 is connected with at its source at an arbitrary positive voltage Vdd and at its drain at the output node 208. The NMOS and PMOS are enhancement mode devices, where both are off if their gate terminal voltage and source terminal voltages are the same. The NMOS device 202 is activated when the drain becomes electrically conductive to the source. This occurs where the gate to source voltage is a small amount higher than the threshold voltage of the device. The PMOS device 204 is activated, where the drain becomes electrically conductive to the source, when the source to gate voltage is a small amount more negative than its threshold voltage. This is a common configuration and is well known. The gates of both M1 202 and M2 204 are connected to the input node 206. The circuit operation is well known, where, if the input node is at zero volts, i.e. at the potential of the source of M1 202, M1 is inactive. And, since the source of M2 204 operates at some arbitrary positive voltage, in the range 2.5 to 5v for example, the device M2 204 is active, where its gate is at a lower voltage value than that of the source terminal. In this condition, the output node 208 is therefore pulled up to the PMOS source voltage Vdd. When the input node 206 is taken to the same potential as the PMOS source VDD, the device M1 202 is now activated, and the device M2 204 de-activated. Thus the output node is now pulled to the same voltage as the NMOS source.

Referring to FIG. 3, one embodiment 300 of the invention is illustrated, where a second tri-state control line “TS” is added. When TS is not asserted or otherwise enabled, the circuit operates in a high or low state. According the invention, the TS control line enables the circuit to act in a third state of operation, a high impedance state. The action of the TS signal via the OR 304, AND 302 and inverter 306 devices is to ensure that, independent of the state of the input signal, “IN”, if “TS” is asserted, for example made active with a signal or taken high, 1) the devices M1 and M2 are both de-activated and 2) the output node “OUT” is neither pulled high nor pulled low. This is when the circuit is in a third state of high impedance. This third state his is well known, as described in for example U.S. Pat. No. 4,037,114. The invention is directed to the novel use of the TS control signal as a means to remove the undesirable click or thud that will be present when a configuration such as this one is initially power up.

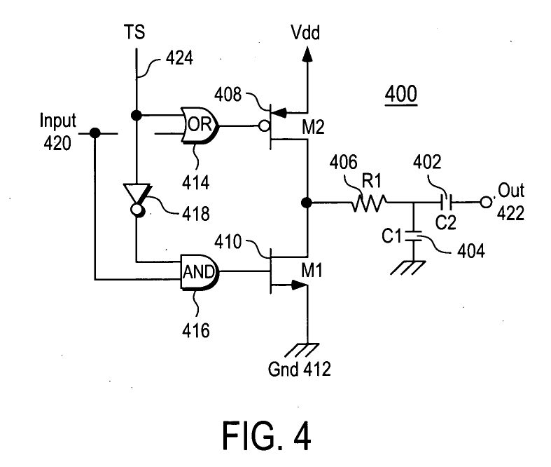

Referring to FIG. 4, the use of the tri-state output of FIG. 3 is explicitly shown with a filter to create the analog output. R1 and C1 form the filter. To create an output that is not “offset” from ground, where the average value is zero as required by any following audio equipment, a DC blocking capacitor C2 is used. This results in a problem that a circuit configured according to the invention solves. At initial first connection or power up of the device, such as at first connection to the capacitor C2 or on first applying the power to the integrated circuit chip, the DC voltage across C2 must adjust such that there is no DC offset. For example, if the positive power were 3.3v the mean voltage output from M1/M2 devices and filter would be typically 1.65v. Thus C2 must accumulate sufficient charge to have an average of 1.65v across it. It is this initial flow of charge to the DC blocking capacitor that causes a “click” or “thud” as the equipment is connected or as the power is first applied.

In one embodiment of the invention, the circuit of FIG. 4 operates as follows. At first power up of the circuit, the inrush current to establish the DC voltage on C2 must flow through either M2 or M1. Therefore devices M2 and M1 are configured to be in the tri-state condition just after power up. This prevents any current flow initially. Then leave the tri-state mode very briefly and then return to tri-state. This causes only a small “packet” of charge to flow, it is small because it can only flow during the time out of the tri-state mode. This brief exit from tri-state did not create a click or thud because the filer R1 C1 that is used to average the output pulses in normal operation also worked to suppress the instantaneous value of this packet of charge. Shortly after this brief time of exit from tri-state the process is repeated - exit tri-state for a slightly longer time, then return to tri-state again. The process is repeated, each time spending longer and longer in non-tri-state mode until finally the tri-state mode is switched off indefinitely. At this time, the circuit is in the normal operating mode. According to the invention, this sequence enables increasingly longer times in non-tri-state mode. The sequence of charge pulses is filtered by the same audio filter that filters the pulses of normal operation. According to the invention, the sequence is gradual. In a preferred embodiment, the sequence is sufficiently slow to ensure that the DC blocking charge is established slowly, and thus the user perceives no click or thud.

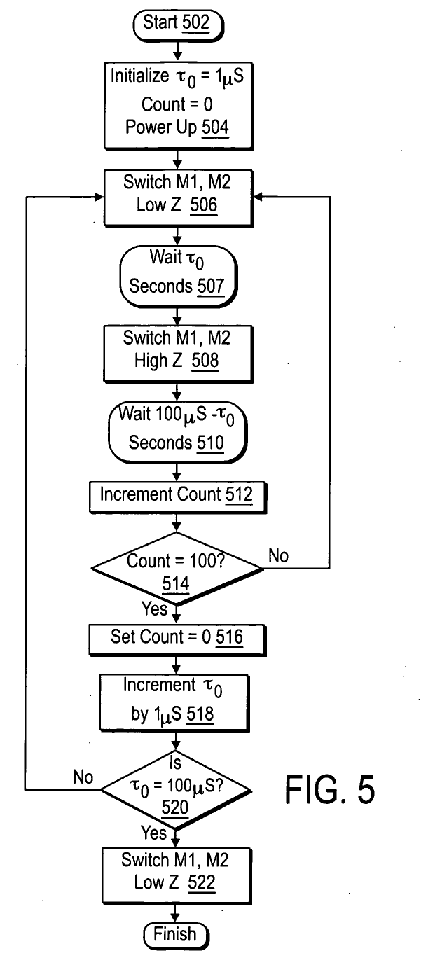

Referring to FIG. 5, one method configured according to the invention is illustrated, where the pulse width keeps increasing, that is the variable t0 that starts at 1 μS (where μ=micro), and increases until it reaches 100 μS. The state variable COUNT is introduced so that it spends 100 cycles of 100 μS at lus. Thus, the system spends 10 mS with 1 μs on time, then spend 10 mS with 2 μs on time, etc. up to 1 omA with 99 μS on time. Therefore, 1 Second is spent powering up. The method begins at step 502, and in step 504 the system is set where t₀=1+S and Count=0 at the time of power up. Then, M1 and M2 are switched to Low Z in step 506. Then, the system waits t₀ seconds in step 507, after which M1 and M2 are switched to High Z in step 508. The system then waits 100μS−t seconds in step 510, and the count is incremented in step 512. In step 514, it is determined whether the count is equal to 100. If no, then the process returns to 506 and cycles until the count is equal to 100. When it is equal to 100 in step 514, then the count is reset to zero in step 516, and to is incremented by 1 μs in step 518. In step 520, it is determined whether t₀=100 μS. If no, then the process returns to step 506 to continue the cycle until it does, or, once t₀=100 μS, the process switches M1 and M2 to Low Z in step 522, and the process ends at step 524.

The invention has been described in the context of direct circuit (“DC”) blocking capacitors to remove a DC offset while generating analog outputs and, in one example, DC blocking capacitors are used in circuits that provide an analog output signal that is then fed to a power amplifier. Those skilled in the art, however, will understand that the invention as well as embodiments described herein have further application, and the invention is not limited to such applications, but is defined by the appended claims and all equivalents.

What we claim is:

1. A signal processing circuit comprising
a first analog signal processing element;
a second analog signal processing element;
a direct current blocking capacitor connecting the first and second analog signal processing elements; and
a controller configured to adjust the impedance of the first analog signal processing element in response to an adjustment signal, wherein the controller is configured to enable the controlling of the establishment of a voltage across the direct current blocking capacitor.

2. A signal processing circuit according to claim 1, wherein the analog signal-processing element is one of a pre-amplifier output, a DAC output, a microphone amplifier output, and any source of an analog audio signal also including a PWM output configured to generate an average output signal.

3. A signal processing circuit according to claim 1, where the second device is one of the input to a power amplifier, a subsequent analog amplification, a processing stage, an ADC converter, a passive element, a loudspeaker, a headphone device and a power bridge device configured to output a high power within an audio system.

4. A circuit according to claim 1, wherein the controller is configured to control the establishment of a voltage as may be required when the state of voltage representing a nominally zero signal is changed

5. A circuit according to claim 1, wherein the controller is configured to control the establishment of the DC voltage as may be required when the state of voltage representing a nominally zero signal is changed, such as in the event of a change of DC voltage level that may be present upon one of 1) the first application and 2) the final removal of power on either of the analog processing elements.

6. A circuit according to claim 1, further comprising an outside signal source transmitting a signal to the controller to control the establishment of the DC voltage.

7. A circuit according to claim 6, wherein the DC voltage may originate in a multiplexing device that is configured to switch an audio signal from one audio program to another as may be used to select TV or DVD or CD or similar.

8. A circuit according to claim 1, further comprising an outside signal source transmitting a signal to the controller to control the establishment of the DC voltage, such as that which may be required when the state of voltage representing a nominally zero signal is changed.

9. A circuit according to claim 8, where the DC Voltage may originate in multiplexing device that is configured to switch an audio signal from one audio program to another as may be used to select one of a TV, DVD, CD and other devices.

10. A circuit according to claim 1, wherein the controller is configured to control the establishment of the DC voltage across the DC blocking capacitor as may be required when the state of voltage representing a nominally zero signal is changed.

11. A circuit according to claim 10, where in the controller is configured to control the establishment of the DC voltage across the DC blocking capacitor in the event of a change of DC voltage level.

12. A circuit according to claim 6, where in the controller is configured to control the establishment of the DC voltage across the DC blocking capacitor in the event of a change of DC voltage level upon the first application of power upon either of the analog processing elements.

13. A circuit according to claim 10, where in the controller is configured to control the establishment of the DC voltage across the DC blocking capacitor in the event of a change of DC voltage level upon the removal of power from either of the analog processing elements.

14. A system configured for signal processing between any two or more connected analog signal processing elements, comprising
a plurality of analog processing elements connected via DC blocking capacitors; and
a signal processing element that operates as the source of the signal employing a controlling means to adjust its output impedance.

15. A system according to claim 14, wherein the controlling means controls the establishment of the DC voltage across the DC blocking capacitor such as may be required when the state of voltage representing zero signal is changed.

16. A system according to claim 15, wherein the voltage representing a nominally zero signal includes a change of DC level that may be present upon first application and final removal of power on an analog processing elements.

17. A method as in claim 14 where the additional impedance controlling means is configured to select one of a finite set of predetermined output impedances.

18. A system according to claim 14, wherein the control of the establishment of the DC voltage across the DC blocking capacitors is achieved by a sequence of selection of predetermined output impedances.

19. A method as in claim 2, where the additional impedance controlling means is configured to select one of two possible output impedances, one a nominally low impedance as may be used in normal operation, and another a nominally high impedance for blocking any substantial current flow.

20. A system according to claim 14, wherein the control of the establishment of the DC voltage across the DC blocking capacitors is achieved by the application of a binary sequence of bits to the controlling means.

21. A system according to claim 20, wherein the sequence of binary bits is configured such that the average output impedance over a defined interval is of a value between that of a nominally low and that of a nominally high output impedance.

22. A method as in claim 21 wherein the sequence of binary bits is constructed such that the output impedance over a defined interval of time progresses gradually from the nominally high output impedance down to the nominally low output impedance to establish the DC value upon either of the first application of power and the first establishment of the nominal operation of any of the analog processing elements.

23. A method as in claim 21 wherein the sequence of binary bits is configured such that the output impedance over a defined interval of time progresses gradually from the nominally low output impedance up to the nominally high output impedance as may be desirable to establish the DC value upon either of the removal of power and the termination of the nominal operation of any of the analog processing elements.

24. A method as in claim 21, wherein the sequence of selection of predetermined output impedances applied to the additional impedance controlling means is at a frequency that is outside a defined range of frequencies transmitted across the connection between the analog signal processing elements.

25. A method as in claim 24 wherein the frequency of selection of predetermined output impedances is at a frequency higher than a frequency transmitted across the connection between the analog signal processing elements.
